(19) United States
(12) Patent Application Publication
(10) Pub. No.: US 2024/0319279 A1
(43) Pub. Date: Sep. 26, 2024

(54) METHOD FOR ESTIMATING THE STATE OF CHARGE OF A BATTERY IN A SYSTEM HAVING A LOW POWER CONSUMPTION, AND SYSTEM FOR IMPLEMENTING THE ESTIMATION METHOD

(71) Applicant: ETA SA Manufacture Horlogère Suisse, Grenchen (CH)

(72) Inventor: José NOIRJEAN, Fornet-Dessus (CH)

(73) Assignee: ETA SA Manufacture Horlogère Suisse, Grenchen (CH)

(21) Appl. No.: 18/417,078

(22) Filed: Jan. 19, 2024

(30) Foreign Application Priority Data
Mar. 20, 2023 (EP) 23162815.7

(51) Int. Cl. G01R 31/367; G01R 31/374; G01R 31/382; H02J 7/00

(52) U.S. Cl. CPC G01R 31/367; G01R 31/374; G01R 31/382; H02J 7/0048; H02J 7/007182; H02J 7/007192; H02J 50/10

(57) ABSTRACT

A method for estimating the state of charge or discharge of a battery or cell of a system having a low power consumption, such as a portable object, which includes at least one power management circuit connected to a battery or cell, and a processing unit of a module connected to the power management circuit. At least one battery voltage value is communicated by the power management circuit to the processing unit of the module to run an algorithm for controlling the state of charge or discharge of the battery, which algorithm is stored in the processing unit so as to provide the state of charge or discharge of the battery or cell.

### TECHNICAL FIELD

The invention relates to a method for estimating the state of charge or discharge of a battery in a system having a low power consumption. The low power consumption system may comprise a portable object such as a watch or an electronic or electromechanical timepiece, which can be powered by a battery or a cell, such as a lithium cell.

The invention further relates to a system for implementing the method for estimating the state of charge or discharge of a battery.

### TECHNOLOGICAL BACKGROUND

Controlling the state of charge of a battery, for example in motor vehicle applications, taking into account the temperature or other parameters is known in the prior art. In the automotive industry, it is easy to develop an application for estimating the state of charge of batteries, as the capacities of these batteries are high and the self-consumption of the system for estimating the state of charge SOC is negligible.

In horological applications, the state of charge of a smart watch is approximated using a look-up table of the battery voltage versus the state of charge of 100 points multiplied by three different temperatures. This solution is limited in that it has a large memory footprint in a ROM-type memory, and in that the accuracy of the method in terms of temperature and absolute accuracy is poor. Moreover, there is no compensation for electrochemical phenomena in the battery, such as the relaxation time between charging and discharging. The recharge phase is estimated by a counter. A lot of peripheral code has to be written to manage the effects of battery relaxation and hysteresis due to the charge and discharge cycles.

It should be noted that the most suitable solution for estimating the battery's state of charge so far is to use a Coulomb counter, which is a circuit that counts the energy drawn from or collected by the battery. However, for the design of watches having an ultra-low power consumption, this electronic circuitry is very expensive in terms of energy and incompatible with a system with an ultra-low power consumption.

The battery power supply in horological applications must be limited to the maximum battery voltage (termination voltage) when fully charged and cannot fall below a minimum battery voltage value (cut-off voltage) so as not to damage the battery available to power the electronic circuit of the watch or timepiece. Galvanic or inductive charging can also be used to charge the battery to a certain extent.

In horological applications or applications involving the system being worn by a person during a sporting activity for example, such as a GPS system, a Coulomb counter as explained above is often used to estimate the state of charge of the battery. However, this type of counter, the power consumption whereof is fairly significant, cannot be used for low-power or low-consumption watches or timepieces. All of the components of a low-power circuit arranged, for example, in a watch case must have a low power consumption and, as a result, the state of charge of the battery is controlled in such a way as to interrupt the supply of power to the electronic circuit from the battery when the voltage level read or measured from the battery approaches or is equal to the low limit voltage which can be set to equal the cut-off voltage of the battery and, when fully charged, to generate a voltage close to the terminal voltage of the battery.

U.S. Pat. No. 10,700,539 B2 describes an electronic device comprising a display and a controller, which obtains time series information regarding an output voltage of a battery so as to detect the state of charge of the battery. The patent states that a mathematical regression is performed to generate a look-up table which is then imported into a microcontroller unit. The look-up table is thus taken into account once it is in the microcontroller unit, which does not allow the state of charge of said battery to be accurately controlled, which constitutes a drawback.

### SUMMARY OF THE INVENTION

The present invention thus proposes a method for estimating the state of charge or discharge of a battery or cell, which method quickly provides information for determining the state of charge or discharge by means of a mathematical regression carried out directly in a processing unit, which can be a microcontroller unit.

This makes it possible to quickly adapt the operating point of an electronic circuit or module completely, thereby overcoming the above-mentioned drawbacks of the prior art. The invention makes it easier to measure a voltage, even with increased precision, and overcomes the above-mentioned drawbacks of the prior art.

To this end, the present invention relates to a method for estimating the state of charge or discharge of a battery or cell, carried out by a low power consumption charge and discharge control system defined in independent claim 1.

Specific steps in the estimation method are defined in dependent claims 2 to 8.

To this end, the present invention further relates to a charge or discharge control system for implementing the low power consumption method for estimating the state of charge or discharge of a battery or cell defined in independent claim 9.

Particular embodiments of the control system are defined in dependent claims 10 to 12.

One advantage of the low-consumption method for estimating the state of charge or discharge of a battery or cell is that the determination is carried out directly in a microcontroller unit of a portable object, which is preferably a watch, which makes it possible to provide the state of charge or discharge of a battery or cell quickly.

An algorithm for controlling the state of charge or discharge of a battery or cell of the portable object, in particular a watch, is integrated in the microcontroller unit, preferably into the electronic module. This allows the state of charge or discharge of the battery to be controlled directly to provide a result quickly.

Advantageously, when the algorithm is put into operation in the microcontroller unit, no Coulomb counter is used, which greatly reduces the electrical current consumed to determine the state of charge or discharge of the battery or cell. Under these conditions, very little power is consumed to determine this state of charge or discharge of the battery or cell in the present invention.

Furthermore, implementing the mathematical regression of the algorithm directly in the microcontroller unit results in a reduced memory footprint for the microcontroller unit.

Another advantage of using the algorithm of the microcontroller unit of the present invention is that it compensates for artefacts on the battery or cell voltage caused by the temperature and the changeover between charging and discharging (hysteresis and relaxation phenomena) of the battery or cell.

### BRIEF DESCRIPTION OF THE FIGURES

The purposes, advantages and features of the low-power or low-consumption method for estimating the state of charge or discharge of a battery or cell and the system for implementing the method will become clearer in the following non-limiting description given with reference to the drawings in which:

FIG. 1 shows a low power consumption system for controlling the state of charge or discharge of a battery or cell for implementing the method for estimating the state of charge or discharge of a battery or cell according to the present invention,

FIG. 2 shows a microcontroller unit of an electronic module, such as a watch module, into which an algorithm for controlling the state of charge or discharge of a battery or cell is integrated for controlling, while consuming little power, the state of charge or discharge of a battery or cell according to the invention,

FIG. 3 shows charge curves for a battery or cell in a low power consumption control system at different temperatures, and

FIG. 4 shows discharge curves for a battery or cell in a low power consumption control system at different temperatures.

### DETAILED DESCRIPTION OF THE INVENTION

The following description describes a method for estimating the state of charge or discharge of a battery or cell of a portable object such as a watch having a low power consumption, as well as the system for implementing the estimation method so as to accurately control the state of charge or discharge of a battery or cell of the watch. Preferably, the watch is equipped with an energy source in the form of a lithium cell. However, other cell types can be envisaged.

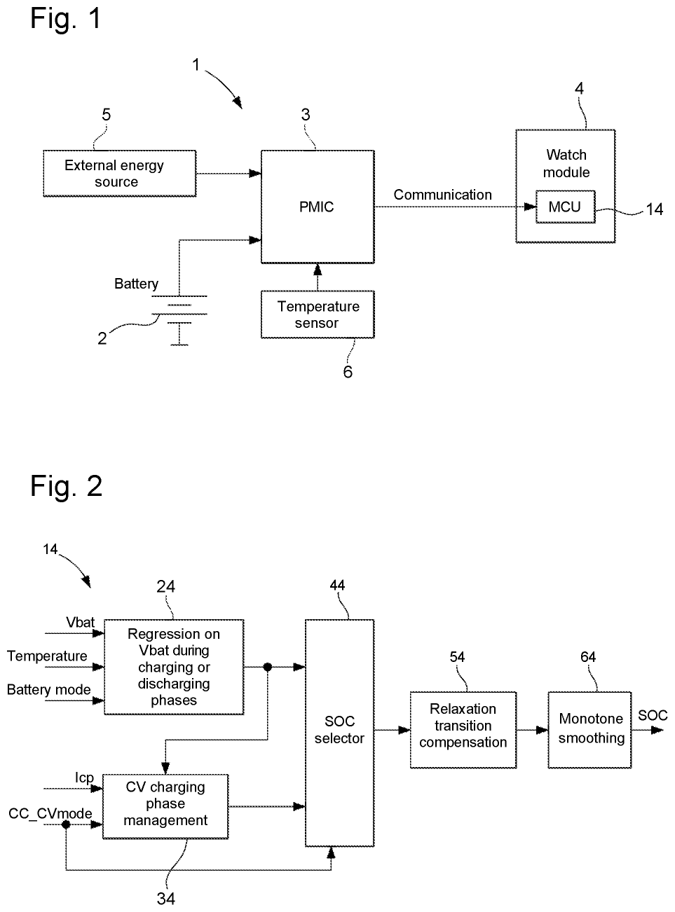

It should be noted that the present invention refers to a system for controlling or estimating the state of charge or even discharge of a low-power battery or cell as shown in FIG. 1. The control or estimation system 1 can be a portable object, powered by a battery or cell 2 and equipped with a power management circuit 3 and a module 4 with a processing unit 14. When the method is implemented, the power management circuit 3 communicates data and/or parameters, including at least a voltage of the battery 2, to the processing unit 14 of the module to run the algorithm for controlling the state of charge or discharge of the cell 2, which algorithm is stored in the processing unit.

The processing unit can preferably be a microcontroller unit 14 and the portable object can be an electronic or electromechanical watch or a timepiece having an ultra-low power consumption and comprising a horological module 4 with a microcontroller unit 14. This power can be consumed in an operating state of the watch system for the method for estimating the state of charge or discharge of a watch battery or cell 2.

During normal operation of the estimation system 1 for an electronic or electromechanical timepiece or watch having a low power consumption, there can be a current consumption of a few μA.

The method for estimating the state of charge or discharge of a battery or a cell 2 of a system 1 having an ultra-low power consumption, such as a portable object, is preferably implemented for a watch or an electronic or electromechanical timepiece.

The system 1 for estimating a charge or discharge of a battery or cell 2 in the watch or timepiece comprises at least the battery or cell 2 connected to a power management integrated circuit 3 referred to as the PMIC. Typically, this integrated circuit 3 allows direct communication with the horological module 4, which comprises a microcontroller unit 14 in which the algorithm for controlling the state of charge or discharge of the cell 2 is stored. The communication carried out by the power management integrated circuit 3 comprises control parameters for running the algorithm stored in the microcontroller unit 14 of the horological module 4. The running of the algorithm in the microcontroller unit 14 will be explained below with reference to FIG. 2 of the method for estimating the state of charge or discharge of a battery or cell. The aim of the algorithm is to quickly provide a state of charge or discharge of the battery or cell 2 to a user of the portable object.

The method for estimating the state of charge or discharge of a battery or cell 2 can be implemented automatically for defined periods.

The system 1 for estimating the charge of a battery or a cell 2, or even the discharge of the battery or cell, can further comprise a temperature sensor 6 supplying a temperature value to the power management integrated circuit 3 so as to be transmitted as a parameter to the microcontroller unit 14 of the horological module 4 for the direct and rapid determination of the state of charge or discharge of the battery or cell by the processing algorithm stored in the microcontroller unit 14. Moreover, an external energy source 5 can be connected to the system 1 in direct connection to the power management integrated circuit 3. This external energy source 5 can be a galvanic charger or an induction charger.

FIG. 2 shows the microcontroller unit 14 with all of the processing elements when the algorithm for controlling the state of charge or discharge of a battery or cell is run. The first functional block 24 takes into account the battery voltage Vbat and the charge or discharge mode. Preferably, this first functional block 24 can further take into account the temperature and the operating mode of the battery (charge or discharge).

The algorithm implements a mathematical regression to be run on real charge or discharge data for the battery or cell, preferably at several temperature levels and with several charge or discharge currents. The coefficients of the regression are then stored in a look-up table and interpolated relative to the measurement temperature.

An output of the first functional block 24 is provided to a second functional block 34 for managing the phase of DC charging voltage (CV) as the initial point of the mathematical regression. Charging in the DC voltage mode uses a percentage of the battery's charge current Icp relative to its maximum charge current and the state of the direct current (DC) and DC voltage (CV) phase or mode. As the battery voltage no longer changes in the CV DC voltage mode, and there is still energy to be supplied in the watch, for example around 15% of the state of charge (SOC), the state of charge is estimated by mathematical regression with the charging current.

A third functional block 44, defined as a state of charge or discharge selector, is connected to the output of the first functional block 24 and to the output of the second functional block 34 and is controlled by the DC current and DC voltage mode state. This block 44 is responsible for switching the SOC value between the CV charge mode and the other modes with mathematical regression of the SOC from the battery voltage.

Switching from a charging current to a discharging current has the effect of creating overvoltage or undervoltage artefacts on the battery voltage that are completely unrelated to the battery's SOC. This is due to electrochemical phenomena in the battery (charge diffusion). In order to “remove” these artefacts, the SOC value will be kept at the previous state prior to the transition, for a fixed time defined by measurement in the fourth functional block 54.

At the battery charge/discharge transition, the SOC value has undergone small rises or falls which do not reflect the state of the SOC (charge or discharge). This is why the SOC value is filtered with a sliding average in the sixth functional block 64.

The proposed algorithm offers the following advantages:
The memory footprint is more compact.
Temperature accuracy is improved.
Relaxation phenomena are taken into account.
The CV DC voltage phase of the charge is taken into account.
The code is simulated, which speeds up its development and the adjustment of its parameters.
The code is generated automatically.

FIG. 3 shows charge curves at different temperatures. The charge curves show each DC-CV transition zone, which are very different and depend on the battery temperature.

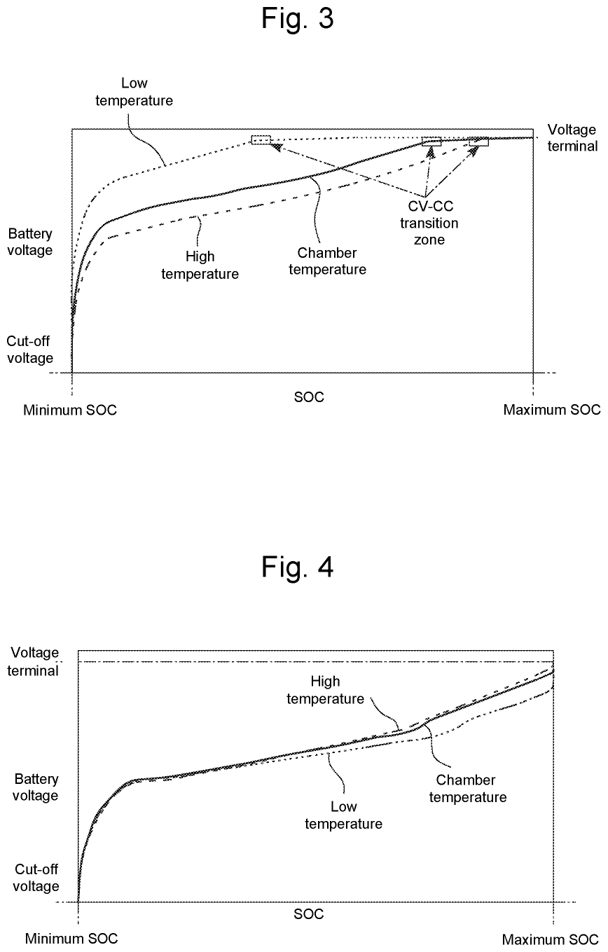

FIG. 4 shows the discharge curves, which demonstrate that the voltage decreases faster at low temperatures than at higher temperatures. In the low-energy region, the battery voltage drops very quickly.

It goes without saying that other embodiments of the system for estimating the state of charge or discharge can be envisaged by a person skilled in the art without departing from the scope of the invention defined by the claims.

1. A method for estimating the state of charge or discharge of a battery or a cell of a system having a low power consumption, wherein said system comprises at least one power management circuit connected to a battery or a cell, and a processing unit of a module connected to the power management circuit,
wherein, when the method for estimating the state of charge or discharge of a battery or cell is implemented, at least one battery voltage value is communicated by the power management circuit to the processing unit of the module to run an algorithm for controlling the state of charge or discharge of the battery or cell, which algorithm is stored in the processing unit so as to provide the state of charge or discharge of the battery or cell.

2. The method according to claim 1, wherein the processing unit of the module is a microcontroller unit of an electronic module, wherein when the method for estimating the state of charge or discharge of the battery or of the cell is implemented, the microcontroller unit is activated by a communication of data and/or parameters from a power management integrated circuit, and wherein, when the microcontroller unit is switched on, the algorithm for controlling the state of charge or discharge of the battery or cell is run in order to determine the state of charge of the battery or cell or the state of discharge of the battery or cell as a function of a selected charge mode or a selected discharge mode of the power management integrated circuit.

3. The method according to claim 1, wherein the algorithm for controlling the state of charge or discharge of the battery or cell is run automatically for defined periods and controlled by the microcontroller unit.

4. The method according to claim 1, wherein a temperature sensor of the system provides a temperature value to the power management circuit during operation of the system for communication as a parameter to the processing unit to allow the algorithm for controlling the state of charge or discharge of the battery or cell to provide a state of charge or discharge of the battery or cell depending on the temperature and operating mode of the battery or cell being charged or discharged.

5. The method according to claim 4, wherein the microcontroller unit runs the algorithm for controlling the state of charge or discharge of the battery or cell, and wherein in a first functional block the algorithm performs a mathematical regression on actual charge or discharge data of the battery or cell for the subsequent storage of coefficients of the regression in a look-up table.

6. The method according to claim 5, wherein the mathematical regression is performed on actual charge or discharge data of the battery or cell at several temperature levels, as well as with several charge or discharge currents, and wherein the coefficients of the mathematical regression are stored in the look-up table and interpolated relative to the measurement temperature.

7. The method according to claim 5, wherein an output of the first functional block is supplied to a second functional block for managing the phase of DC charging voltage, and wherein a third functional block defines a state of charge or discharge, by being connected to the output of the first functional block and to the output of the second functional block and by being controlled by a DC current and DC voltage mode state, and wherein said third functional block is responsible for switching between a charging mode (CV) and a main mode with the mathematical regression of the battery voltage.

8. The method according to claim 7, wherein the transition from a charging current to a discharging current creates overvoltage or undervoltage artefacts on the battery or cell voltage, wherein a previous state of charge or discharge prior to the transition is maintained for a fastened time previously defined by a measurement in a fourth functional block following the third functional block, and wherein finally, in a sixth functional block following the fifth functional block, filtering is performed by a sliding average.

9. A system for implementing the method according to claim 1, wherein the system comprises at least one power management circuit connected to a battery or a cell, and a processing unit of a module connected to the power management circuit.

10. The system according to claim 9, wherein the processing unit of the module is a microcontroller unit of a horological module.

11. The system according to claim 9, wherein said system comprises a temperature sensor connected to the power management circuit.

12. The system according to claim 9, wherein said system comprises an external energy source, originating from a galvanic charger or an inductive charger.
